(19) United States
(12) Patent Application Publication
(10) Pub. No.: US 2008/0146031 A1
(43) Pub. Date: Jun. 19, 2008

(54) Method for forming a semiconductor structure

(75) Inventors: Hung Jen Liu, Taipei (TW); Wei Hsien Hsieh, Taipei (TW); Chang-Ho Yeh, Taipei (TW)

Correspondence Address: BIRCH STEWART KOLASCH & BIRCH, PO BOX 747, FALLS CHURCH, VA, 22040-0747, US

(73) Assignee: NANYA TECHNOLOGY CORPORATION

(21) Appl. No.: 12/000,538

(22) Filed: Dec. 13, 2007

(30) Foreign Application Priority Data
Dec. 14, 2006 (TW) 95146817

(51) Int. Cl. H01L 21/461

(52) U.S. Cl. 438/689; 257/E21.483

(57) ABSTRACT

A method for semiconductor structure formation includes: providing a substrate; forming a first lower mask layer on the substrate; forming a first patterned mask on the first lower mask layer; forming a second lower mask layer on the first lower mask layer and overlaying the first patterned mask; forming a second patterned mask on the second lower mask layer without the second patterned mask overlapping the first patterned mask; etching and undercutting the first lower mask layer and the second lower mask layer to form the third patterned mask with the first patterned mask and the second patterned mask; etching the substrate by using the third patterned mask to form a plurality of islands; and removing the third patterned mask.

### RELATED APPLICATIONS

This application claims the right of priority based on Taiwan Patent Application No. 095146817 entitled “METHOD FOR SEMICONDUCTOR STRUCTURE FORMATION”, filed on Dec. 14, 2006, which is incorporated herein by reference and assigned to the assignee herein.

### FIELD OF THE INVENTION

The present invention generally relates to a method for forming a semiconductor structure, and more particularly, to a method for forming a semiconductor with reduced feature width.

### BACKGROUND OF THE INVENTION

In the semiconductor manufacture industry, photolithography and etching technologies both are well known in the art. Traditionally, a single opening or island formation only employs patterning processes once, which generally includes forming a patterned photoresist on an etching object to define an etching area, followed by using the patterned photoresist as a mask to etch the object. However, as the size of semiconductor devices is continuously reduced and the integrated density is increased, the layout of circuitry and devices on a given area becomes more and more complicated. As the number of openings or islands to be formed increases, the layout density of the patterned photoresist requires a correspondingly increase. In order to improve the layout density of the patterned photoresist for a given area, the width of each patterned feature has to be reduced, or the resolution of the lithography process must be improved. Reducing the feature width might narrow the patterned feature and cause the patterned feature to collapse. Moreover, the improvement of resolution requires advanced lithography equipment, and accordingly, the cost is high. Consequently, using the existing equipment to form a patterned feature, such as opening or island, with a small width or in a dense configuration is highly desirable.

Therefore, there is a need to provide a method for increasing the density of openings or islands without upgrading the existing equipment.

### SUMMARY OF THE INVENTION

One aspect of the present invention is to provide a method for forming a semiconductor structure. This method increases the number of patterned features and improves the feature density, i.e. to produce more islands for a given area. This method implements the undercut etching to prevent the patterned photoresist from collapse due to narrowness and form an island feature with a smaller width.

In one embodiment, the present invention is to provide a method for forming a semiconductor structure. The method includes: providing a substrate; forming a first lower mask layer on the substrate; forming a first patterned mask on the first lower mask layer; forming a second lower mask layer over the first lower mask layer and covering the first patterned mask; forming a second patterned mask on the second lower mask layer without overlapping the first patterned mask; undercut etching the first lower mask layer and the second lower mask layer to form a third patterned mask by using the first patterned mask and the second patterned mask; etching the substrate by using the third patterned mask to form a plurality of islands; and removing the third patterned mask.

### BRIEF DESCRIPTION OF THE DRAWINGS

FIG. 1 to FIG. 7 illustrates schematic cross-sectional views of a method for forming a semiconductor structure at different stages in accordance with one embodiment of the present invention.

### DETAILED DESCRIPTION

The present invention discloses a method for forming a semiconductor structure.

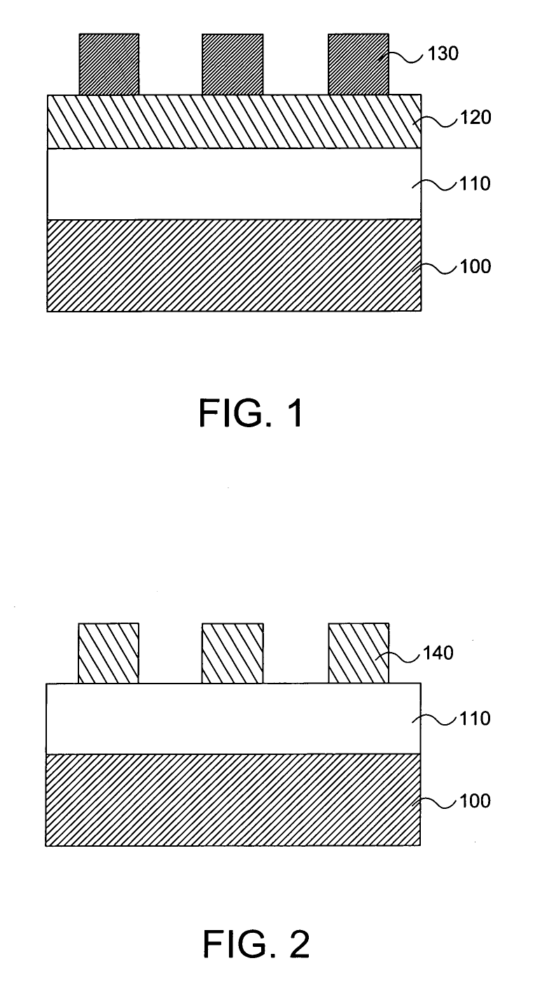

For better understanding, please refer to the following descriptions in conjunction with the accompanied drawings, FIG. 1 to FIG. 7.

With reference to FIGS. 1 and 2, the present invention provides a method for forming a semiconductor structure. The method includes the step of providing a substrate 100, which can be a conductor layer, a dielectric layer, or an insulating layer etc during any stage of manufacturing a semiconductor device. It is noted that each layer described in the embodiment is not limited to specific materials as long as the manufacturing process is able to fulfill the requirements of the present invention. In the embodiment, the substrate 100 can be a semiconductor substrate, such as Si substrate, Ge substrate, Silicon-On-Insulator (SOI) substrate or SiGe On Insulator (SGeOI) substrate, etc.

Next, a first lower mask layer 110 is formed on the substrate 100 by a deposition technology, such as spin on deposition, physical vapor deposition or chemical vapor deposition, but is not so limited. The first lower mask layer 110 can be made of organic materials such as photoresist etc., or inorganic materials such as a hard mask, for example, SION or Carbon etc. Then, a first upper mask layer 120 is formed on the first lower mask layer 110 by for example, a deposition process as described above. Followed by a photography process, a first patterned photoresist 130 is formed on the first upper mask layer 120 to define a first patterned mask 140.

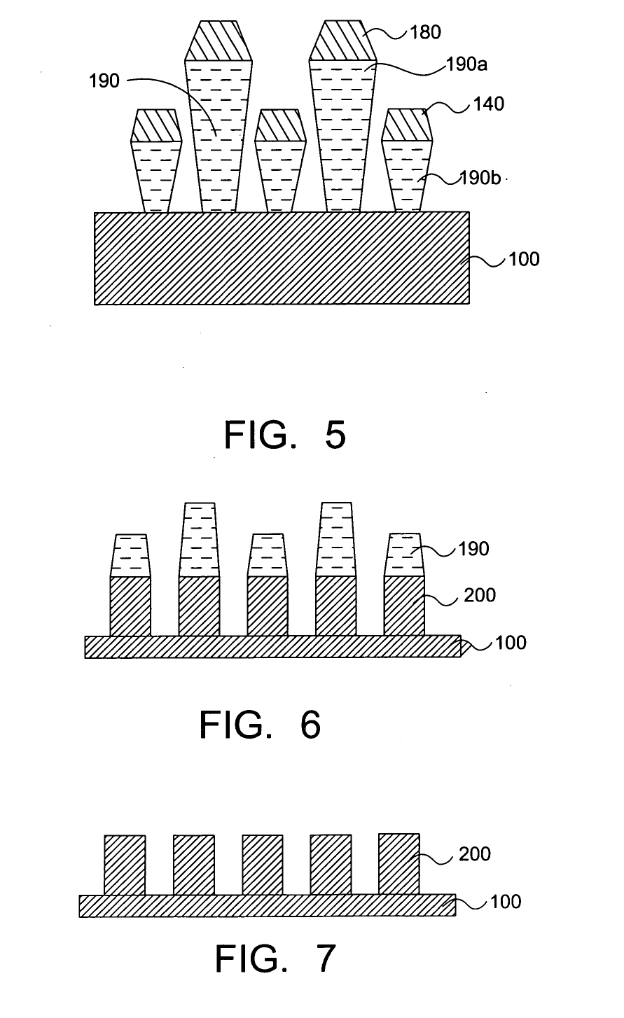

With reference to FIG. 2, the first upper mask layer 120 is etched by using the patterned photoresist 130 as an etching mask to form the first patterned mask 140. The first patterned mask 140 serves as a hard mask to define a first part of a third patterned mask 190 (see FIG. 5). After the first upper mask layer 120 is etched, the first patterned photoresist 130 is removed.

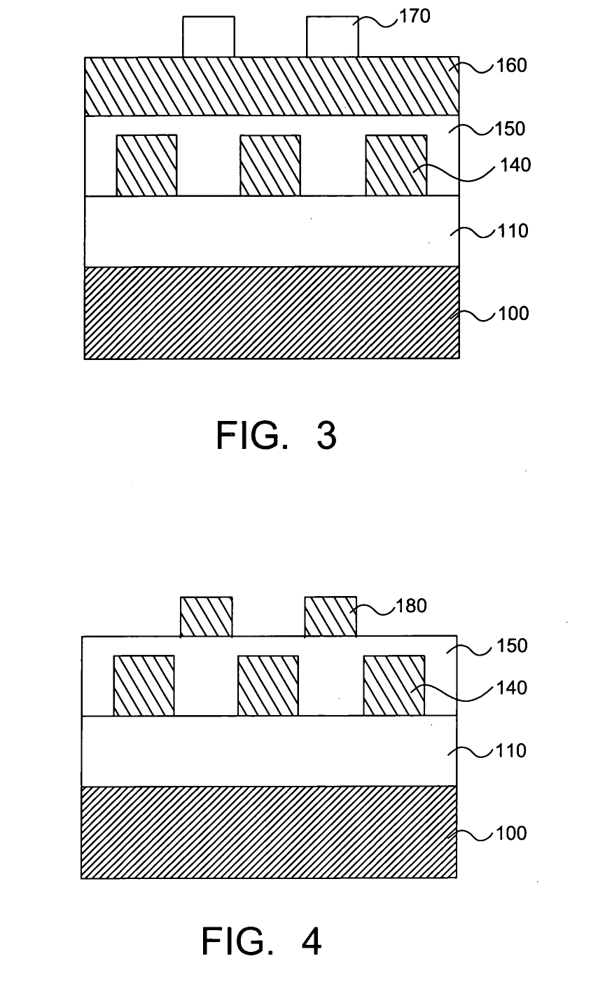

With reference to FIGS. 3 and 4, a second lower mask layer 150 is formed on the first lower mask layer 110 and covers the first patterned mask 140. The second mask layer 150 can be organic materials, such as photoresist etc., or inorganic materials, such a hard mask, for example, SiON or Carbon etc. Then, a second upper mask layer 160 is formed on the second lower mask layer 150. Followed by a photolithography process, a second patterned photoresist 170 is formed on the second upper mask layer 160 to define a second patterned mask 180. It should be noted that for the purpose of increasing density of the defined area, the second patterned mask 180 and the first patterned mask 140 are not overlapped with each other. That is, the second patterned photoresist 170 does not overlap the first mask layer 140 and voids of the second patterned photoresist 170 are alternately defined relative to voids of the first mask layer 140. Afterwards, by using the second patterned photoresist 170 as a mask, the second upper mask layer 160 is etched to form the second patterned mask 180. The second patterned mask 180 serves as a hard mask to define a second part of the third patterned mask 190 (see FIG. 5). After the second upper mask layer 160 is etched, the second patterned photoresist 170 is removed.

With reference to FIG. 4, by using the first patterned mask 140 and the second patterned mask 180 as an etching mask to undercut etch the second lower mask layer 150 and the first lower mask layer 110 so as to form the third patterned mask 190 with an upper portion 190a and a lower portion 190b. The undercut etch is performed by an anisotropic etch process, such as plasma etch, associated with adjustments of process parameters, such as gas flow rate, power, pressure, and the likes. The etch process can be appropriately controlled to form the third patterned mask 190 which is tapered in shape. In other words, the third patterned mask 190 has a tapered shape, and the upper portion 190a has a dimension greater than that of the lower portion 190b. It should be noted that when using the mask layers, such as 140 and 180, as a protecting mask, the upper mask layers (120, 160) and the lower mask layers (110, 150) should have an etching selective ratio, and the preferred ratio is 1: 5˜10.

With reference to FIG. 5, after the step of plasma undercut etching, the third patterned mask 190 is formed. The third patterned mask 190 includes a plurality of patterned features in a tapered shape, and each patterned feature includes the first patterned mask 140, the second patterned mask 180 and the underlying lower mask layer. Next, ash shown in FIG. 6, by using the third patterned mask 190 as a mask, the substrate 100 is etched to form a plurality of islands 200. It should be noted that the number of the islands 200 is the sum of the number of features of the first patterned mask 140 and the number of features of the second patterned mask 180, i.e. the total number of the features defined by the first patterned photoresist 130 and the second patterned photoresist 170. The feature width of the islands 200 is smaller than the feature width of the first patterned photoresist 130 or the features width of the second patterned photoresist 170 due to the undercut etching. Then, the third patterned mask 190 is removed. Consequently, the island features 200 are formed with a feature width smaller than the resolution of photolithography process achieved, and the feature density of the islands 200 is also increased by the two-step patterning processes. Therefore, the purpose for reducing width of the patterned feature without additional equipment cost is achieved.

By means of the detailed descriptions of what is presently considered to be the most practical and preferred embodiments of the subject invention, it is expected that the features and the gist thereof be clearly described. Nevertheless, these embodiments are not intended to be construed in a limiting sense. Instead, it will be well understood that any analogous variations and equivalent arrangements will fall within the spirit and scope of the invention.

What is claimed is:

1. A method for forming a semiconductor structure, comprising:
providing a substrate;
forming a first lower mask layer on said substrate;
forming a first patterned mask on said first lower mask layer;
forming a second lower mask layer over said first lower mask layer and covering said first patterned mask;
forming a second patterned mask on said second lower mask layer, and the second patterned mask being alternately formed relative to the first patterned mask;
undercut etching said first lower mask layer and said second lower mask layer to form a third patterned mask;
etching said substrate by using said third patterned mask to form a plurality of islands; and
removing said third patterned mask.

2. The method for forming a semiconductor structure of claim 1, wherein the step for forming said first patterned mask comprises:
depositing a first upper mask layer on said first lower mask layer;
forming a first patterned photoresist on said first upper mask layer to define said first patterned mask;
etching said first upper mask layer to form said first patterned mask by using said first patterned photoresist as a mask, to define a first part of said third patterned mask; and
removing said first patterned photoresist.

3. The method for forming a semiconductor structure of claim 2, wherein the step for forming said second patterned mask comprises:
depositing a second upper mask layer on said second lower mask layer;
forming a second patterned photoresist on said second upper mask layer to define said second patterned mask;
etching said second upper mask layer to form said second patterned mask by using said second patterned photoresist as a mask, to define a second part of said third patterned mask; and
removing said second patterned photoresist.

4. The method for forming a semiconductor structure of claim 1, wherein said first lower mask layer, said second lower mask layer, said first upper mask layer or said second upper mask layer is formed by spin coating, physical vapor deposition or chemical vapor deposition.

5. The method for forming a semiconductor structure of claim 1, wherein said island has a width smaller than a feature width of at least one of said first patterned mask and said second patterned mask.

6. The method for forming a semiconductor structure of claim 1, wherein the number of said islands is a sum of the number of features of said first patterned mask and the number of features of said second patterned mask.

7. The method for forming a semiconductor structure of claim 3, wherein the number of said islands is a sum of the number of features of said first patterned mask and the number of features of said second patterned mask.

8. The method for forming a semiconductor structure of claim 5, wherein the number of said islands is a sum of the number of features of said first patterned mask and the number of features of said second patterned mask.

9. The method for forming a semiconductor structure of claim 1, wherein said third patterned mask comprises an upper portion and a lower portion, and said upper portion has a dimension larger than that of said lower portion.

10. The method for forming a semiconductor structure of claim 1, wherein said third patterned mask is tapered in shape.

11. The method for forming a semiconductor structure of claim 6, wherein said third patterned mask is tapered in shape.

12. The method for forming a semiconductor structure of claim 7, wherein said third patterned mask is tapered in shape.

13. The method for forming a semiconductor structure of claim 8, wherein said third patterned mask is tapered in shape.

14. The method for forming a semiconductor structure of claim 11, wherein said third patterned mask comprises an upper portion and a lower portion, and said upper portion has a dimension larger than that of said lower portion.

15. The method for forming a semiconductor structure of claim 12, wherein said third patterned mask comprises an upper portion and a lower portion, and said upper portion has a dimension larger than that of said lower portion.

16. The method for forming a semiconductor structure of claim 13, wherein said third patterned mask comprises an upper portion and a lower portion, and said upper portion has a dimension larger than that of said lower portion.
